(19) United States
(12) Patent Application Publication
(10) Pub. No.: US 2011/0315826 A1
(43) Pub. Date: Dec. 29, 2011

(54) RAM AIR INFLATING LIFTING BODY

(75) Inventor: Allan Brocklebank, Cambridge (GB)

(73) Assignee: THE SECRETARY OF STATE FOR DEFENCE, London (GB)

(21) Appl. No.: 13/255,941

(22) PCT Filed: Mar. 15, 2010
(86) PCT No.: PCT/GB10/00456

§ 371 Date: Sep. 12, 2011

(30) Foreign Application Priority Data
Mar. 19, 2009 (GB) 0904664.0

(51) Int. Cl. B64C 3/54; H01L 31/042

(52) U.S. Cl. 244/218; 136/244

(57) ABSTRACT

The invention relates to an improved ram air inflating lifting body (1) such as a para-foil. The lifting body (1) being configured so as to be controllable by changing the effective chord length (5) of at least one of the surfaces (2, 3) of the lifting body and thus the aerodynamic properties of the lifting body (1).

This invention relates to an improved ram air inflating lifting body and more particularly to a means for controlling such a lifting body.

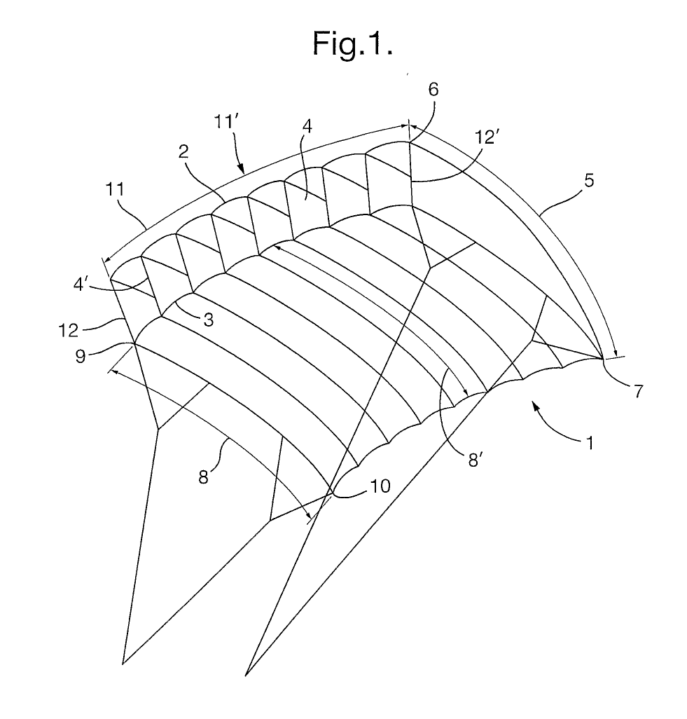

Ram air inflating lifting bodies are well known and often referred to as para-foils or inflatable canopies. A ram air inflating lifting body is shown in FIG. 1. Such bodies are partially if not wholly constructed from flexible materials which are inflated as an air stream passes into the body. The inflated body then provides aerodynamic lift by virtue of its shape. Such bodies are often constructed with a cell structure which attaches an upper surface to a lower surface so as to channel the air stream into the structure to fully inflate the body.

Ram air inflating lifting bodies are used to provide aerodynamic lift in a variety of applications varying from parachutes, from which various payloads or indeed people can be suspended, to wings for lightweight or model aircraft and kites of all designs.

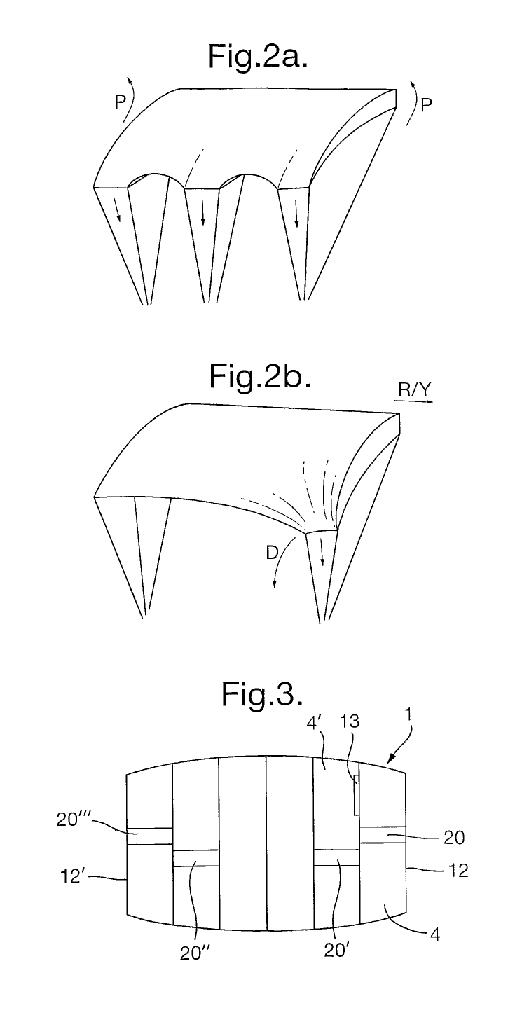

Known ram air inflating lifting bodies are controlled by control lines attached to the lifting body which can be pulled or released so as to deform the shape of the lifting body and thus change the aerodynamic properties of the lifting body. Deformation is generally performed at the trailing edge of the lifting body. If this deformation is performed symmetrically along the span of the lifting body as shown in FIG. 2a this will change the pitch (P) of the lifting body and thus the relative velocity of the lifting body to the air stream and the lift provided by the lifting body. If this deformation is performed asymmetrically along the span of the lifting body as shown in FIG. 2b then the deformation will cause asymmetric drag (D) and cause the lifting body to roll and/or yaw (R/Y) thus allowing directional control of the lifting body. FIG. 2b shows, by way of example, deformation causing a right turn.

Some known embodiments of ram air inflating lifting bodies utilise trailing edge flaps or extensions which can be moved to provide a similar effect to changing the shape of the lifting body itself However in such embodiments the shape, and thus the aerodynamic properties, of the lifting body itself does not change.

The use of known control lines provides a cheap and simple means for providing control for lifting bodies however such control lines have inherent problems in that they are susceptible to be becoming damaged, entangled or snagged on the lifting body itself either upon deployment or in flight thus reducing their effectiveness in controlling the lifting body or resulting in a loss of control. Also such know control lines increase the overall drag of the lifting body therefore reducing its aerodynamic efficiency. As such a reduction in the number of control lines used is advantageous as it increases the aerodynamic efficient of the lifting body and reduces the risk of control lines becoming tangled, damaged or snagged.

It is an object of the present invention to provide an alternative means of controlling a ram air inflating lifting body. The lifting body being configured so as to be controllable by changing the aerodynamic shape of the lifting body and thus the aerodynamic properties of the lifting body.

Accordingly, the present invention provides a ram air inflating lifting body having aerodynamic properties comprising a flexible upper surface having an upper effective chord length attached directly or indirectly to a flexible lower surface having a lower effective chord length wherein the upper and lower surfaces each-have a span with the respective spans having a tip at each extremity of the span characterized in that the lifting body further comprises at least one control means for changing at least one of the effective chord lengths thereby changing the aerodynamic properties of the lifting body.

The upper and/or lower effective chord length(s) may vary between points across the span of the lifting body as a result of the overall design of the lifting body. An example of such a lifting body, in the form of an elliptical canopy, is shown in FIG. 3.

The upper and/or lower effective chord length(s) can be reversibly increased or decreased by using the control means to increase or decrease the chord length of the upper and/or lower surface(s). As further detailed below, the change(s) can be made across the whole span of the lifting body or at specific points along the span. Changing one or more of the effective chord lengths will change the overall shape of the lifting body, either across the whole span or at a specific point along the span, and therefore the aerodynamic properties of the lifting body. Changing the shape of the lifting body in a controlled fashion will thus enable the lifting body to be controlled in flight.

Advantageously the control means may comprise at least one roller device. The roller device may usefully be arranged in co-operation with the flexible lower surface and/or the flexible upper surface. Such a configuration allows the flexible lower and/or upper surface to be respectively ‘rolled up’ or ‘rolled out’ to decrease or increase the respective lower and/or upper effective chord length(s).

In flight aerodynamic forces acting on the lifting body will act to inflate the body to the maximum extent possible. As such when increasing or ‘rolling out’ the upper or lower surface the resulting change in overall shape of the lifting body will be assisted by the aerodynamic forces associated with the ram air inflation of the lifting body however this same force will act against any decreasing or ‘rolling up’ of the upper or lower surface. To reduce the overall force required to decrease the upper or lower effective chord length the roller device can advantageously utilise a torsion spring or other mechanism to act against the aerodynamic force.

Alternatively, or in addition to the use of the roller device, the control means may advantageously comprises at least one linear actuator. Where more than one linear actuator is used the linear actuators can act individually to decrease or increase the respective lower and/or upper effective chord length(s) or, advantageously, two or more linear actuators can act together to increase or decrease an individual effective chord length thus allowing for the potential use of smaller linear actuators. The linear actuator may be any suitable actuator however examples will exclude a solenoid or a solid state device. The linear actuator may usefully be arranged in co-operation with the flexible lower surface and/or the flexible upper surface. Such a configuration allows the flexible lower and/or upper surface to be ‘contracted’ or ‘extended’ to respectively decrease or increase the respective lower and/or upper effective chord length(s). The contraction or extension of the flexible lower and/or upper surface could be achieved by any applicable means however examples of such means may include one or more of stretching of the material which forms the upper and/or lower surface(s), folding part of the upper and/or lower surface(s) over upon itself and constructing the lower and/or upper surface(s) of a plurality of elements said elements together producing an effective chord length for the respective lower and/or upper surface wherein the elements are arranged such that the at least one linear actuator can move at least one of the elements in relation to the other element(s) to increase or decrease the effective chord length of the upper and/or lower surface(s).

When increasing or ‘extending’ the upper or lower surface the resulting change in overall shape of the lifting body will be assisted by the aerodynamic forces associated with the ram air inflation of the lifting body however this same force will act against any decreasing or ‘contracting’ of the upper or lower surface. To reduce the overall force required to decrease the upper or lower effective chord length the linear actuator can advantageously utilise an extension spring or other mechanism to act against the aerodynamic force.

In order to reduce any drag caused by the control means and any power supply required to power the control means the control means and/or any power supply could be located within the ram air lifting body. Advantageously the upper and or lower surface(s) may comprise a plurality of layers with the control means and/or any power supply located within the plurality of layers. Further the control means and/or any power supply can be located within any means for attaching the upper surface to the lower surface such as the internal elements of a cell structure. Said cell structure may also consist of a plurality of layers within which the control means and/or any power supply can be located.

As stated previously control of the lifting body is achieved by changing the shape of the lifting body.

If the shape of the lifting body is changed symmetrically across the span of the lifting body this will control the lifting body in pitch, causing the lifting body to pitch up or down. Such control can be achieved by a single control means according to the present invention changing at least one of the upper and/or lower effective chord lengths or by a plurality of the control means acting together or independently to change at least one of the upper and/or lower effective chord lengths.

In order to control the lifting body in roll and/or yaw, thus allowing directional control of the lifting body, the shape of the lifting body must be changed asymmetrically across the span of the lifting body. This can be achieved by a single control means according to the present invention acting at a point away from a centre point of the span of the lifting body however, advantageously a plurality of control means according to the present invention can be used with at least two of the control means arranged so as to be controllable independently of one another thus allowing the shape of the lifting body to be changed asymmetrically across the span of the lifting body.

Where a plurality of control means according to the present invention are used these control means can be positioned across the span of the lifting body however, in order to gain greater control it is advantageous to have more of the control means according to the present invention located at positions closer to the tips of the span than at positions closer to a centre point of the span. Such an arrangement provides a greater control moment in roll and yaw when the control means are utilised asymmetrically.

In order to gain maximum control it is believed that the control means according to the present invention should be positioned at the mid point of the upper and/or lower chord length.

The control means according to the present invention could be controlled by manual control lines similar to those used on conventional ram aim inflating lifting bodies. However the control mean(s) according to the present invention can advantageously be motorised and controlled by a link between a controller and the control means. The controller can be pre-programmed to control the lifting body to fly a particular trajectory. This can, advantageously be assisted using a known global positioning system. Motorising the control means removes the need for standard control lines therefore reducing drag caused by the control lines and reducing the dangers caused by the lines becoming damaged, entangled or snagged. Even more advantageously the motorised control means according to the present invention are linked to the controller by a wireless link thus removing the need for any physical link between the control means and the controller.

The controller can be located on the ground or slung beneath the lifting body on a person or as a payload. Advantageously the controller is located on the lifting body itself. To reduce drag the controller may be located within the structure of the lifting body as described for the control means or power supply.

Motorising the control means means that a source of energy will be needed. Energy can be provided by batteries or other source of stored energy such as compressed fluids however advantageously a ram air inflating lifting body according to present invention can include at least one solar panel. The at least one solar panel can advantageously be located on, or form part of, the flexible upper surface.

Embodiments of the invention will now be described with reference to the accompanying figures:

FIG. 1 is a known ram air inflating lifting body.

FIG. 2a shows the control of a lifting body in pitch.

FIG. 2b shows the control of a lifting body in roll and/or yaw.

FIG. 3 is a plan view of ram air inflating lifting body according to the present invention.

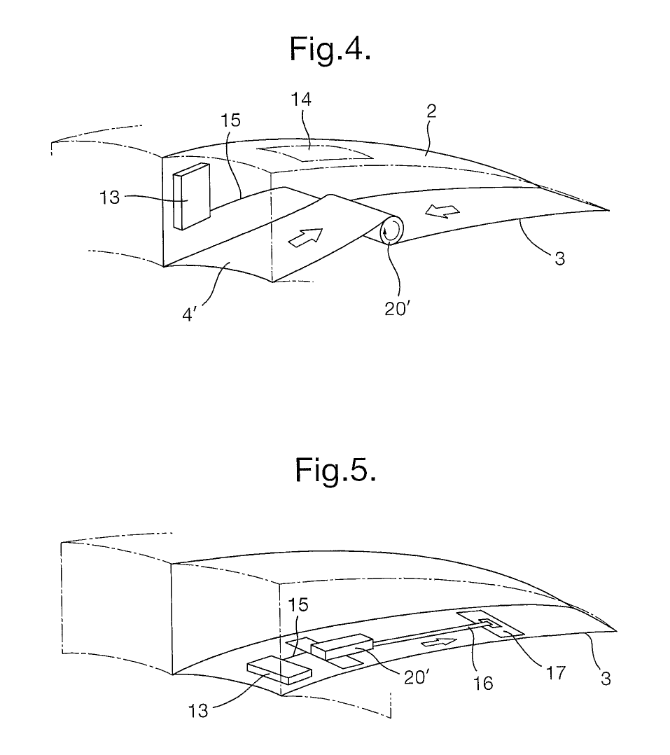

FIG. 4 shows one cell of a lifting body according the present invention.

FIG. 5 shows one cell of a lifting body according an alternative embodiment of the present invention.

FIG. 1 shows a general arrangement of a ram air inflating lifting body 1. The lifting body 1 having an upper surface 2 and a lower surface 3, the upper surface 2 and the lower surface 3 being attached to one another by a cell structure 4, 4′. The lifting body 1 also has a span 11 having a centre point 11′ and a tip 12, 12′ at each extremity of the span. The upper surface 2 has an effective chord length 5, being the length of the upper surface 2 at a specific point along the span measured in a straight line along the upper surface from a leading edge 6 of the upper surface 2 to a trailing edge 7 of the upper surface 2. The trailing edge 7 is shown in FIG. 1 as ‘closed’ wherein the upper surface 2 is directly attached to the lower surface 3. The trailing edge 7 may however be ‘open’ wherein the upper surface 2 is not directly attached to the lower surface 3 thus allowing increased airflow through the lifting body 1. The lower surface 3 has a lower effective chord length 8, 8′ being the length of the lower surface 3 at a specific point along the span 11 measured in a straight line along the lower surface from the leading edge 9 of the lower surface 3 to the trailing edge 10 of the lower surface 3.

A plan view of the arrangement of a lifting body according to the present invention is shown in FIG. 3. The lifting body 1 comprises a plurality of cells 4, 4′. The two cells closest to the tip 12 of the lifting body 1 each have a control means 20, 20′ attached in co-operation with the lower surface 3 of the lifting body. A symmetrical arrangement of control means 20″ and 20″′ are located in the two cells closet to the tip 12′ of the lifting body 1. The lifting body 1 further comprises a controller 13 which includes a suitable power source and a pre-programmable means for controlling the trajectory of the lifting body. The controller 13 is mounted on the inside of the cell structure 4′. The controller 13 is shown mounted within, and projecting into, the cell structure 4′ of the lifting body 1 however the cell structure 4′ may be constructed of a plurality of layers (not shown) which would allow the controller 13 to be mounted within the plurality of layers thus reducing drag. The controller 13 can be used to control all the control means 20, 20′, 20″ and 20″′. These control means can be controlled individually by the controller 13 so as to control the trajectory of the lifting body 1. In a preferred embodiment the control means and controller are linked via a wireless connection.

The cell 4′ is shown in more detail in FIG. 4 however the arrangement in FIG. 4 could be applied to any or all of the cells in the lifting body 1. In this embodiment the control means 20′ can be seen to be a roller device. The roller device is arranged in co-operation with the flexible lower surface 3 of the lifting body 1. Such a configuration allows the flexible lower surface to be ‘rolled up’ as indicated by the arrows or ‘rolled out’ to decrease or increase the lower effective chord length and thus change the aerodynamic properties of the lifting body 1.

The roller device 20′ is driven by a motor (not shown) either within the roller device 20′ itself or mounted separately. The motor is controlled by the controller 13 by a direct link 15. Power for the motor can come from the controller or a power source mounted separately however FIG. 4 shows a solar panel mounted on the upper surface 2 of the lifting body 1 which is configured to provide power to the roller device 20′. In order to assist with overcoming aerodynamic forces when reducing the lower effective chord length 8 of the lower surface 3 a torsion spring (not shown) is provided in cooperation with the roller device 20′.

A further embodiment of the invention is shown in FIG. 5. In this embodiment the control means 20′ can be seen to be a linear actuator. The linear actuator has an arm 16 which is connected to the lower surface 3 of the lifting body 1 at a point 17. The arm 16 can be made from a rigid or flexible material as the aerodynamic force acting on the lifting body will assist with when increasing or ‘extending’ the lower surface in the direction of the arrow. However this same force will act against any decreasing or ‘contracting’ of the lower surface. To reduce the overall force required to decrease the lower effective chord length the linear actuator advantageously utilises an extension spring (not shown) in co-operation with the linear actuator and lower surface 3.

As with the embodiment shown in FIG. 4 the linear actuator 20′ is driven by a motor (not shown) either within the linear actuator 20′ itself or mounted separately. The motor is controlled by the controller 13 by a direct link 15. Power for the motor can come from the controller or a power source mounted separately such as a solar panel as shown in FIG. 4 mounted on the upper surface 2 of the lifting body 1.

1. A ram air inflating lilting body having aerodynamic properties comprising a flexible upper surface having an upper effective chord length attached to a flexible lower surface having a lower effective chord length wherein the upper and lower surfaces each have a span with the respective span having a tip at each extremity of the span wherein the lifting body further comprises at least one control means for changing at least one of the effective chord lengths thereby changing the aerodynamic properties of the lifting body.

2. A ram air inflating lifting body according to claim 1 wherein the at least one control means comprises a roller device.

3. A ram air inflating lifting body according to claim 2 wherein the roller device further comprises a torsion spring.

4. A ram air inflating lifting body according to claim 1 wherein the at least one control means comprises a linear actuator.

5. A ram air inflating lifting body according to claim 4 wherein the linear actuator further comprises an extension spring.

6. A ram air inflating lifting body according to claim 1 wherein the at least one control means is arranged in co-operation with the flexible lower surface.

7. A ram air inflating lifting body according to claim 1 wherein the at least one control means is arranged in co-operation with the flexible upper surface.

8. A ram air inflating lifting body according to claim 1 wherein the at least one control means is arranged in co-operation with the flexible lower surface and the flexible upper surface.

9. A ram air inflating lifting body according to claim 1 wherein at least one of the lower or upper surface comprises a plurality of layers and the at least one control means is located within the layers.

10. A ram air inflating lifting body according to claim 1 wherein the lifting body comprises a plurality of control means and at least two of the control means are arranged so as to be controllable independently of one another.

11. A ram air inflating lifting body according to claim 10 wherein more of the control means are located at positions closer to the tips of the span than at positions closer to a centre point of the span.

12. A ram air inflating lifting body according to claim 1 wherein the lifting body further comprises a controller for controlling the control means.

13. A ram air inflating lifting body according to claim 1 wherein the at least one control means is motorised.

14. A ram air inflating lifting body according to claim 13 wherein the at least one control means is controlled by a wireless link.

15. A ram air inflating lifting body according to claim 1 wherein the flexible upper surface comprises at least one solar panel.

16. (canceled)
